(19) United States
(12) Patent Application Publication
(10) Pub. No.: US 2021/0343577 A1
(43) Pub. Date: Nov. 4, 2021

(54) LIFT PIN AND VACUUM PROCESSING APPARATUS

(71) Applicant: ULVAC, INC., Chigasaki-shi (JP)

(72) Inventors: Yoshiaki YAMAMOTO, Chigasaki-shi (JP); Yosuke JIMBO, Chigasaki-shi (JP); Takehisa MIYAYA, Chigasaki-shi (JP); Kenji ETO, Chigasaki-shi (JP); Yoichi ABE, Chigasaki-shi (JP)

(21) Appl. No.: 16/329,047

(22) PCT Filed: Aug. 6, 2018
(86) PCT No.: PCT/JP2018/029408

§ 371 Date: Feb. 27, 2019

(30) Foreign Application Priority Data
Nov. 21, 2017 (JP) 2017-223792

(51) Int. Cl. H01L 21/687; H01J 37/32; C23C 16/50; C23C 16/458

(52) U.S. Cl. CPC H01L 21/68742; H01J 37/32715; C23C 16/50; H01J 2237/3321; H01J 2237/20235; H01J 37/32082; C23C 16/458

(57) ABSTRACT

A lift pin of the invention is to be in contact with a substrate having a process-target surface and a non-processed surface, and the lift pin includes: a center member that has a first surface having first surface roughness and including an electrical insulator, and a main body serving as an electroconductive member, and that faces the non-processed surface of the substrate; and a surrounding member that has a second surface having second surface roughness lower than the first surface roughness and including an electrical insulator, that surrounds the periphery of the center member, and that faces the non-processed surface of the substrate.

### TECHNICAL FIELD

The present invention relates to a lift pin and a vacuum processing apparatus.

This application claims priority from Japanese Patent Application No. 2017-223792 filed on Nov. 21, 2017, the contents of which are incorporated herein by reference in their entirety.

### BACKGROUND ART

Conventionally, when a substrate that is an object to be processed is transferred in a vacuum processing apparatus, a lift pin that sends and receives the substrate between a transfer arm and a substrate holder is known. The lift pin is provided inside a substrate holder on which the substrate is to be mounted, protrudes from a top surface of the substrate holder, and thereby sends and receives the substrate.

As a configuration that prevents damage to a substrate from being generated due to contact of the lift pin with a back surface of the substrate, a lift pin has been proposed which has a corner subjected to an R beveling process (refer to Patent Document 1). In addition, in terms of strength or corrosion resistance, ceramic is commonly used as a constituent material of the lift pin (refer to Patent Document 2).

### PRIOR ART DOCUMENTS

### Patent Documents

### (Patent Document 1) Japanese Unexamined Patent Application, First Publication No. 2014-11166

(Patent Document 2) Japanese Unexamined Patent Application, First Publication No. H11-340309

### SUMMARY OF THE INVENTION

### Problems to be Solved by the Invention

The substrate holder has a substrate mounting surface on which the substrate is to be mounted and a plurality of opening holes that open at the substrate mounting surface. The number and the position of the opening holes correspond to the number and the position of lift pins. The lift pin relatively moves up and down so as to penetrate the substrate holder inside the opening hole, raises the substrate, or puts the substrate on the upper surface of the substrate holder.

However, on the substrate mounting surface of the substrate holder, electrical lines of force or a temperature of the region on which the opening hole is formed are locally different from those of a region on which the opening hole is not formed. Due to this, there is a problem in that becomes non-uniform which is generated above the top surface of the substrate mounted on the substrate mounting surface. As plasma becomes non-uniform, of a substrate which was subjected to treatment such as film coating or etching, a film-thickness profile thereof becomes non-uniform or etching uniformity becomes degraded. As a result, it causes defects of a device including TFT (Thin Film Transistor) or the like which is formed on the substrate.

Although Patent Document 1 discloses a configuration that prevents damage to a substrate from being generated due to contact of the lift pin with the substrate, the configuration of the lift pin does not contribute to solving the problem in that plasma becomes non-uniform.

The invention was made in view of the above-described situation, and has an object to provide a lift pin that prevents damage to a back surface of a substrate from being generated and can improve uniformity of plasma generated above a top surface of the substrate and a vacuum processing apparatus provided with the lift pin.

### Means for Solving the Problems

As a result of intensive research to solve the aforementioned problem by the inventors, although it was found that a generation of damage to a back surface of a substrate is prevented by R beveling process in the case of the lift pin disclosed by Patent Document 1, a gap between the lift pin and the substrate becomes large at the portion that was subjected to the R beveling process, and therefore plasma becomes non-uniform. Furthermore, the inventors conceived that, due to plasma being non-uniform, it is difficult to carry out film formation with a uniform film-thickness profile or carry out uniform etching.

Additionally, in the case of the lift pin disclosed by Patent Document 2, there is an attempt to obtain electroconductivity by metalizing ceramic material; however, the strength thereof becomes degraded during use conditions at a high temperature, and it has not been put into practical use.

Under the aforementioned knowledge, the inventors obtained the invention in order to solve the above-mentioned problems.

A lift pin according to a first aspect of the invention includes: a center member that includes: a first surface having a first surface roughness and including an electrical insulator; and a main body that is an electroconductive member, the center member facing the substrate; a surrounding member that includes a second surface having a second surface roughness smaller than the first surface roughness and including an electrical insulator, the surrounding member surrounding a periphery of the center member, the surrounding member facing the substrate.

In the lift pin according to the first aspect of the invention, the surrounding member may be an electrical insulating member.

In the lift pin according to the first aspect of the invention, the surrounding member may be an electroconductive member.

In the lift pin according to the first aspect of the invention, the center member and the surrounding member may form an integrated body formed of an electroconductive member.

In the lift pin according to the first aspect of the invention, the first surface and the second surface may have a curved surface so that a center position of the center member on the first surface in a direction in which the lift pin extends is located outside an end position of the surrounding member on the second surface.

In the lift pin according to the first aspect of the invention, a corner located between an outer surface of the surrounding member and the second surface of the surrounding member may have a curved surface.

In the lift pin according to the first aspect of the invention, the first surface and the second surface may be contactable to the substrate.

A vacuum processing apparatus according to a second aspect of the invention includes: a vacuum chamber; a substrate holder having a substrate mounting surface on which the substrate is to be mounted, an opening hole that opens at the substrate mounting surface, the substrate holder being disposed inside the vacuum chamber; the lift pin according the above-described first aspect which is provided at a position corresponding to the opening hole and is capable of moving up and down in a vertical direction inside the opening hole; a high-frequency power supply that generates plasma in the vacuum chamber; and a lifting mechanism that moves the lift pin relative to the substrate holder in a vertical direction.

### Effects of the Invention

According to the aspects of the invention, damage to a back surface of a substrate is prevented from being generated, and it is possible to improve uniformity of plasma generated above a top surface of the substrate.

### BRIEF DESCRIPTION OF THE DRAWINGS

FIG. 1 is a cross-sectional view partially showing a vacuum processing apparatus according to an embodiment of the invention.

FIG. 2 is a plan view showing a substrate to be mounted on a heater in the vacuum processing apparatus according to the embodiment of the invention and is a view showing positions of lift pins that lifts and lowers a substrate.

FIG. 3A is a view showing the lift pin according to the embodiment of the invention and is a top view showing the lift pin.

FIG. 3B is a view showing the lift pin according to the embodiment of the invention and is a longitudinal cross-sectional view showing the lift pin.

FIG. 4 is an enlarged cross-sectional view showing a state where the lift pin according to the embodiment of the invention is in contact with a back surface of a substrate.

FIG. 5 is an enlarged cross-sectional view showing a state where the lift pin according to the embodiment of the invention is accommodated in the heater.

FIG. 6 is a cross-sectional view showing a relevant part of a modified example 1 of the lift pin according to the embodiment of the invention.

FIG. 7 is a cross-sectional view showing a relevant part of a modified example 2 of the lift pin according to the embodiment of the invention.

FIG. 8 is a cross-sectional view showing a relevant part of a modified example 3 of the lift pin according to the embodiment of the invention.

FIG. 9 is a cross-sectional view showing a relevant part of a modified example 4 of the lift pin according to the embodiment of the invention.

FIG. 10 is a cross-sectional view showing a relevant part of a modified example 5 of the lift pin according to the embodiment of the invention.

FIG. 11A is an explanatory diagram showing the invention.

FIG. 11B is an explanatory diagram showing the invention.

### EMBODIMENTS FOR CARRYING OUT THE INVENTION

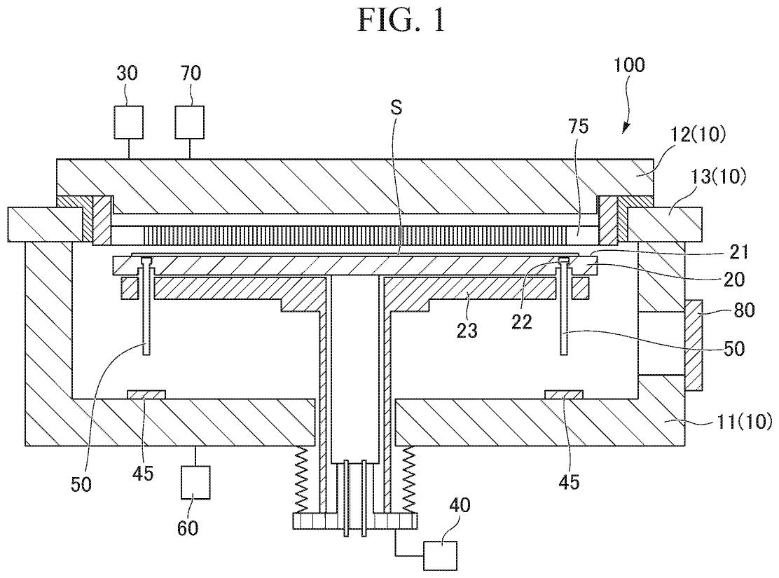

A lift pin and a vacuum processing apparatus according to an embodiment of the invention will described with reference to FIGS. 1 to 5. In the respective drawings used for explanation of the embodiment, individual members are enlarged so as to be recognizable, and thus the reduced scales of the individual members are appropriately changed.

### (Vacuum Processing Apparatus)

In the embodiment described below, for an example, the case will be described where the vacuum processing apparatus is applied to a plasma CVD apparatus (film formation apparatus).

As shown in FIG. 1, a vacuum processing apparatus 100 according to the embodiment includes a vacuum chamber 10, a heater 20 (substrate holder), a high-frequency power supply 30, a lifting mechanism 40, lift pins 50, a vacuum pump 60, a gas supplier 70, and a door valve 80.

### (Vacuum Chamber)

The vacuum chamber 10 includes a lower chamber 11, an upper chamber 12, and an electrode flange 13 held between the lower chamber 11 and the upper chamber 12.

### (Heater)

The heater 20 is disposed inside the vacuum chamber 10 and is formed of aluminum serving as an electroconductive member. The heater 20 has a mounting surface 21 on which a substrate S is to be mounted and a plurality of opening holes 22 which penetrate through the heater 20 and open at the substrate mounting surface 21. A heater base 23 is provided on the back surface of the heater 20 on the opposite side of the substrate mounting surface 21.

The lift pin 50 which will be described later is disposed (accommodated) inside the opening hole 22, and the lift pin 50 is capable of moving up and down in a vertical direction inside the opening hole 22. Additionally, a bushing (not shown in the figure) that prompts the lift pin 50 to smoothly move upwardly and downwardly and a bushing bolt that fixes the bushing to the opening hole 22 are provided inside the opening hole 22.

As shown in FIG. 5, the opening hole 22 has an upper opening 22U that opens at the substrate mounting surface 21 and a lower opening 22L that is located under the upper opening 22U. The diameter of the upper opening 22U is slightly larger than the diameter of a surrounding member 52 of the lift pin 50, for example, 10.5 mm.

The diameter of the lower opening 22L is slightly larger than the diameter of the tubular member 54 of the lift pin 50, for example, 7.5 mm.

The depth 22D of the upper opening 22U is slightly larger than the lengths of the surrounding member 52 and the ring member 53 of the lift pin 50, for example, 6.5 mm.

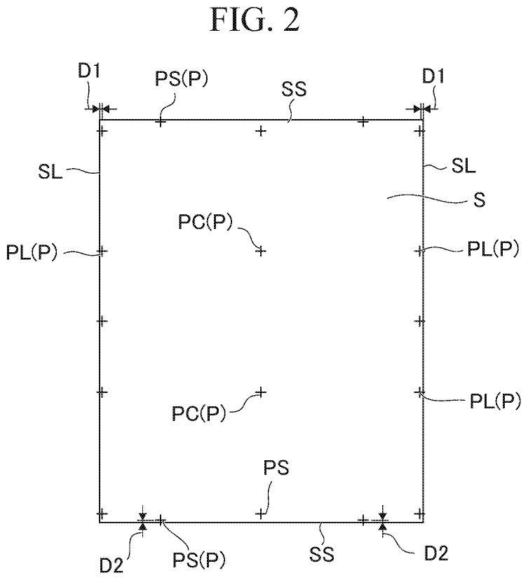

FIG. 2 shows the substrate S to be mounted on the substrate mounting surface 21 of the heater 20 and the positions P of the lift pins 50 that lift and lower the substrate S. Note that, since the lift pins 50 are disposed at the opening holes 22, the positions (center position) of the opening holes 22 correspond to the positions P.

The substrate S can be moved up and down by ten lift pins 50 (position PL) located close to the long side SL of the substrate S, six lift pins 50 (position PS) located close to the short side SS of the substrate S, two lift pins 50 (position PC) located at the substantially center of the substrate S, that is, by eighteen lift pins 50 in total.

The position PL of the lift pin 50 located closest to the long side SL of the substrate S is separated from the end of the long side SL of the substrate S by the distance D1. The position PS of the lift pin 50 located closest to the short side SS of the substrate S is separated from the end of the short side SS of the substrate S by the distance D2. For example, the distances D1 and D2 are each approximately 10 mm to 14 mm.

Note that, the number of the lift pins 50 in the embodiment is eighteen; however, the number of the lift pins 50 is not limited, in consideration of flexibility or the like of the substrate S, the number thereof may be greater than or equal to nineteen or may be less than or equal to seventeen.

### (High-Frequency Power Supply)

The high-frequency power supply 30 is provided outside the vacuum chamber 10 and is electrically connected to a cathode electrode provided inside the vacuum chamber 10 via a matching box and a wiring which are not shown in the figure. When the high-frequency power supply 30 is activated and matched high-frequency power (RF) is supplied to the cathode electrode, plasma is generated inside the vacuum chamber 10.

### (Lifting Mechanism)

The lifting mechanism 40 moves the lift pin 50 relative to the heater 20 in a vertical direction. Specifically, the lifting mechanism 40 can change a position of the heater 20 in the vertical direction (direction of gravitational force), due to downward movement of the heater 20, the lift pin 50 comes into contact with a lift pin base 45, and the lift pin 50 protrudes from the substrate mounting surface 21. At this time, in the case where the substrate S is mounted on the substrate mounting surface 21, the lift pins 50 raise the substrate S.

### (Vacuum Pump)

The vacuum pump 60 is connected to an exhaust port formed at the vacuum chamber 10 via a pressure adjustment valve and a pipe which are not shown in the figure. It is possible to maintain a vacuum state inside the vacuum chamber 10 by driving the vacuum pump 60 and it is possible to remove gas that remains inside the vacuum chamber 10 after a processing is completed. Additionally, as the vacuum pump 60 and the pressure adjustment valve are driven in a state where a processing gas is supplied to the inside of the vacuum chamber 10, it is possible to control a pressure inside the vacuum chamber 10 depending on processing conditions.

### (Gas Supplier)

The gas supplier 70 is connected to a gas supply port formed at the vacuum chamber 10 via a mass-flow controller and a pipe which are not shown in the figure. The kind of gas which is supplied from the gas supplier 70 may be appropriately selected depending on the kind of processing in the vacuum chamber 10, for example, a film formation processing, etching processing, an ashing processing, or the like. The gas supplied from the gas supplier 70 is supplied to the vacuum chamber 10 and thereafter is supplied toward the substrate S through a shower plate 75.

### (Door Valve)

The door valve 80 includes an opening-closing drive mechanism which is not shown in the figure. When the door valve 80 opens, a transfer arm which is not shown in the figure transfers the substrate S to the inside of the vacuum processing apparatus 100 or transfers the substrate S from the vacuum processing apparatus 100. When the door valve 80 is closed, the vacuum chamber 10 is in a hermetically-closed state, and it is possible to process the substrate S inside the vacuum chamber 10.

The vacuum processing apparatus 100 may include a cleaning device that cleans surfaces of members inside the vacuum chamber 10 by supplying a gas such as NF₃ to a discharge space inside the vacuum chamber 10. As such cleaning device, a device using remote plasma is adopted.

### (Lift Pin)

The lift pin 50 is configured to come into contact with the substrate S having a process-target surface that is subjected to a processing by the vacuum processing apparatus and a non-processed surface on the opposite side of the process-target surface. The non-processed surface of the substrate S corresponds to a back surface SB which will be described later.

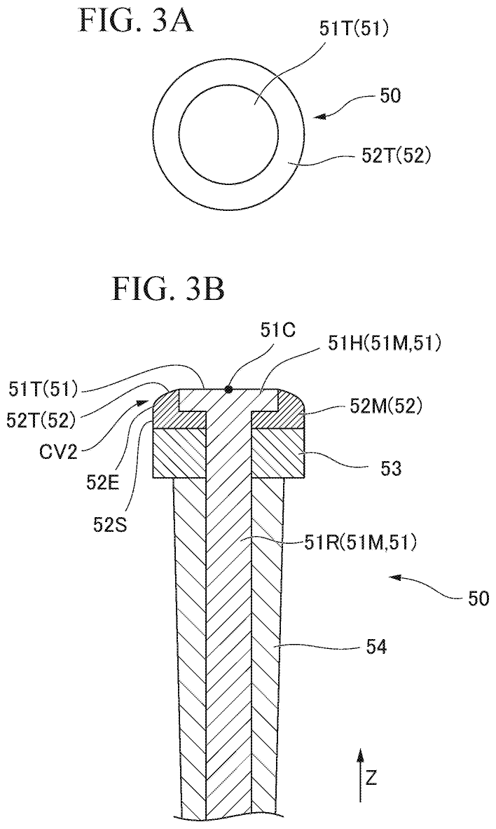

As shown in FIGS. 3A and 3B, each of the lift pins 50 includes a center member 51, the surrounding member 52, the ring member 53, and the tubular member 54.

### (Center Member)

The center member 51 includes a main body 51M that is an electroconductive member and a first surface 51T that is an upper surface of the main body 51M. The main body 51M has a T-shape in cross-sectional view and includes head 51H and a rod 51R.

As a material of the main body 51M, for example, aluminum is adopted. An alumite coating (electrical insulator) on which aluminum is subjected to anodic oxidation treatment is formed on the first surface 51T.

The surface roughness (first surface roughness) of the alumite coating formed on the first surface 51T can be appropriately modified depending on the conditions of the anodic oxidation treatment, for example, a surface roughness Ra of 1 to 2 μm is adopted.

In addition, since the rod 51R is electrically connected to the heater 20, the rod 51R and the heater 20 are maintained in the same electrical potential.

The diameter of the head 51H of the center member 51 is, for example, 6.4 mm.

In the embodiment, the first surface 51T has a flat surface (flat); however, the invention is not limited to this structure. The first surface 51T and the second surface 52T may have a curved surface so that the center position 51C of the center member 51 on the first surface 51T in the direction in which the lift pin 50 extends (the Z-direction) is located outside the end position 52E of the surrounding member 52 on the second surface 52T. The shape of the curved surface may be, for example, a spherical surface, a gradual paraboloidal surface, or a non-spherical surface such as a semi-ellipse surface. From the viewpoint that processing is easy and the optimum value is easily determined, the curved surface is preferably a spherical surface. As mentioned above, in the case where the first surface 51T of the center member 51 that constitutes the lift pin 50 is a curved surface, the back surface SB of the substrate S and the first surface 51T smoothly come into contact with each other, and damage to the back surface SB of the substrate S is prevented from being generated.

### (Surrounding Member)

The surrounding member 52 surrounds the periphery of the center member 51, particularly, surrounds the side surface of the head 51H and the connection portion between the head 51H and the rod 51R.

In the embodiment, the surrounding member 52 includes a main body 52M that is an electrical insulating member and the second surface 52T that is an upper surface of the main body 52M. The second surface 52T is a curved surface and constitutes an electrical insulator.

As a material of the main body 52M, for example, insulating ceramic such as alumina, zirconia, aluminum nitride, silicon nitride, or silicon carbide is adopted. The surface roughness (second surface roughness) of the second surface 52T is smaller than the surface roughness of the first surface 51T, for example, a surface roughness Ra of 0.2 μm is adopted.

The diameter of the surrounding member 52 is, for example, 9.5 mm.

A corner located between the outer surface 52S of the surrounding member 52 and the second surface 52T of the surrounding member 52 has a curved surface CV2. In other words, the corner located between the outer side surface 52S and the second surface 52T is subjected to chamfering processing.

The ring member 53 is located under the surrounding member 52 and surrounds the periphery of the rod 51R of the center member 51. As a material of the ring member 53, for example, aluminum is adopted.

The tubular member 54 is located under the ring member 53 and surrounds the periphery of the rod 51R of the center member 51. As a material of the tubular member 54, for example, insulating ceramic is adopted.

Next, the action of the vacuum processing apparatus 100 provided with the lift pin 50 having the configuration described above will be described.

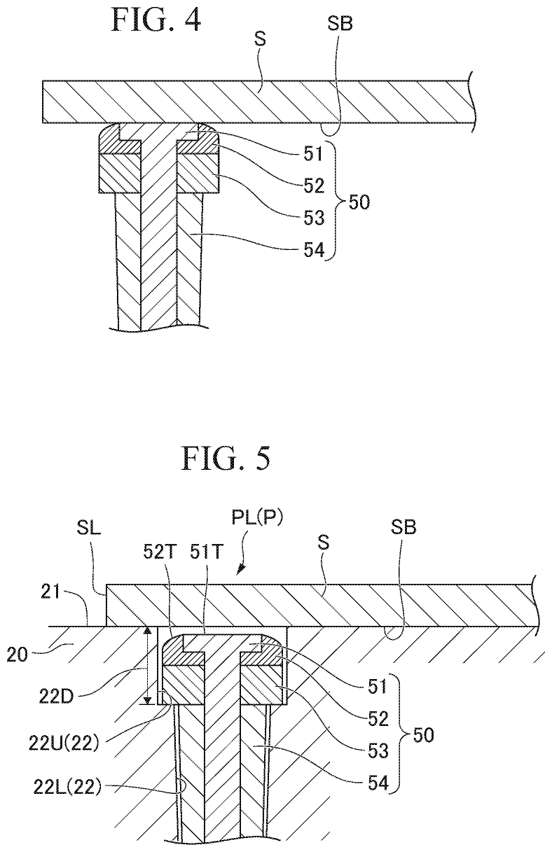

In the vacuum processing apparatus 100, as the lifting mechanism 40 is driven and the lift pins 50 thereby move up toward the upper side of the substrate mounting surface 21, the lift pins 50 is in a state of being capable of receiving the substrate S. Thereafter, the transfer arm transfers the substrate S to the space above the substrate mounting surface 21 and the substrate S is passed from the transfer arm to the lift pins 50. At this time, as shown in FIG. 4, the first surface 51T of the lift pin 50 comes into contact with the back surface SB of the substrate S, and the lift pin 50 receives the substrate S from the transfer arm. When the above-described transferring is carried out, there is a case where the substrate S vibrates, the substrate S comes into contact with the second surface 52T due to this vibration in some cases. However, since the surface roughness of the second surface 52T is smaller than that of the first surface 51T, damage to the back surface SB of the substrate S due to contact between the second surface 52T and the substrate S is prevented from being generated. Furthermore, since the curved surface CV2 is formed on the corner of the lift pin 50, that is, on the second surface 52T, the back surface SB of the substrate S and the second surface 52T smoothly come into contact with each other, and therefore damage to the back surface SB of the substrate S is prevented from being generated. In other words, since the curved surface CV2 is formed on the corner of the lift pin 50, there is no possibility that a sharp corner comes into contact with the back surface SB of the substrate S.

Next, as the lifting mechanism 40 is driven, the lift pins 50 that maintain the substrate S move downward, the substrate S is mounted on the substrate mounting surface 21, and the lift pins 50 are accommodated in the opening holes 22 of the heater 20 as shown in FIG. 5. In this state, the center member 51 and the surrounding member 52 face the back surface SB of the substrate S at the position P shown in FIG. 2.

Next, in a state where the door valve 80 is closed, due to operation of the vacuum pump 60, pressure adjustment valve, the high-frequency power supply 30, and the gas supplier 70, plasma of the processing gas is generated above the substrate S, and a film is formed on the substrate S. Here, similar to the heater 20, the center member 51 of the lift pin 50 is formed of the electroconductive member and is electrically connected to the heater 20, and the center member 51 and the heater 20 have the same electrical potential. Consequently, the state of the plasma generated above the substrate S corresponding to the position P of the lift pin 50 becomes the same as the state of the plasma generated above the substrate S located on the substrate mounting surface 21 on which the lift pin 50 is not formed, plasma is uniformly generated, and a film having a uniform film-thickness profile is formed on the substrate S.

After the film formation is completed, as the lifting mechanism 40 is driven and the lift pins 50 thereby move up toward the upper side of the substrate mounting surface 21, the lift pins 50 raise the substrate S as shown in FIG. 4, and the transfer arm receives the substrate S. When the above-described transferring is carried out, there is a case where the substrate S vibrates in a similar way as in the above described transfer. Also in this case, since the surface roughness of the second surface 52T is smaller than that of the first surface 51T, damage to the back surface SB of the substrate S due to contact between the second surface 52T and the substrate S which is caused by the vibration of the substrate S is prevented from being generated. Furthermore, since the curved surface CV2 is formed on the corner of the lift pin 50, that is, on the second surface 52T, the back surface SB of the substrate S and the second surface 52T smoothly come into contact with each other, and therefore damage to the back surface SB of the substrate S is prevented from being generated. In other words, since the curved surface CV2 is formed on the corner of the lift pin 50, there is no possibility that a sharp corner comes into contact with the back surface SB of the substrate S. The transfer arm that received the substrate S takes out the substrate S from the vacuum chamber 10.

As described above, in the vacuum processing apparatus 100 according to the embodiment, since the surface roughness of the second surface 52T is smaller than that of the first surface 51T, damage to the back surface SB of the substrate S due to the contact between the second surface 52T and the substrate S can be prevented from being generated.

Furthermore, the center member 51 is formed of an electroconductive member and is electrically connected to the heater 20, and therefore the center member 51 and the heater 20 have the same electrical potential. Because of this, even in cases where the lift pins 50 are accommodated in the opening holes 22, plasma to be generated above the substrate S does not become non-uniform, and it is possible to form a film having a uniform film-thickness profile on the substrate S by uniform plasma.

Particularly, although the position PL located closest to the long side SL of the substrate S or the position PS located closest to the short side SS of the substrate S is the portion above which plasma easily becomes non-uniform, as a result of employing the aforementioned configuration, plasma can be uniformly generated above the positions PL and PS, and it is possible to form a film having a uniform film-thickness profile.

### Modified Example 1 of Lift Pin

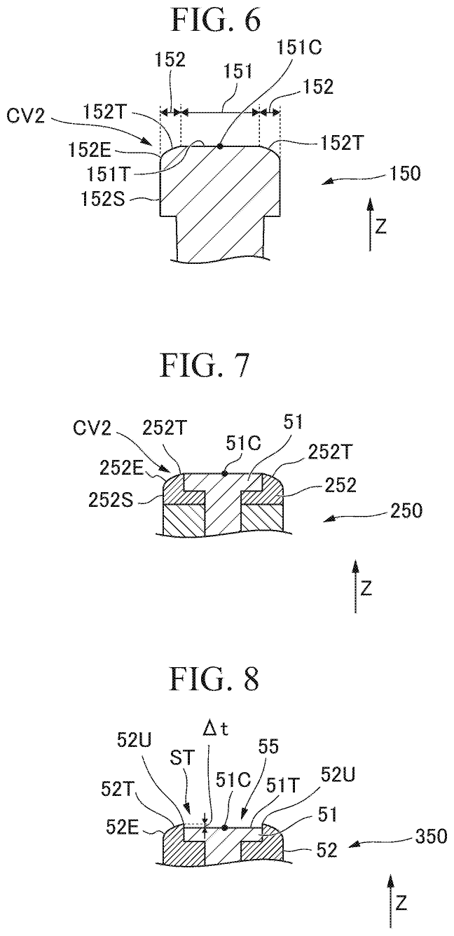

FIG. 6 is a cross-sectional view showing a relevant part of a configuration of a modified example 1 of the lift pin according to the embodiment of the invention. In FIG. 6, identical reference numerals are used for the elements which are identical to those of the embodiment, and explanations thereof are omitted or simplified here.

The modified example 1 is different from the above-mentioned embodiment in that a center member and a surrounding member form an integrated body formed of an electroconductive member.

Specifically, a lift pin 150 includes a center region 151 (center member) and a surrounding region 152 (surrounding member) and is an integrated body formed by aluminum (electroconductive member). That is, a boundary is not formed between the center region 151 the surrounding region 152. Although an alumite coating (electrical insulator) on which aluminum is subjected to anodic oxidation treatment is formed on a first surface 151T of the center region 151 and a second surface 152T of the surrounding region 152, the surface roughness of the first surface 151T is different from that of the second surface 152T, the surface roughness (second surface roughness) of the second surface 152T is smaller than the surface roughness of the first surface 151T.

Particularly, as the surface roughness of the first surface 151T, for example, a surface roughness Ra of 1 to 2 μm is adopted. Additionally, as the surface roughness of the second surface 152T, for example, a surface roughness Ra of 0.2 μm is adopted.

In the modified example 1, the first surface 151T has a flat surface (flat); however, the invention is not limited to this structure. The first surface 151T and the second surface 152T may have a curved surface so that the center position 151C of the center region 151 on the first surface 151T in the direction in which the lift pin 150 extends (the Z-direction) is located outside the end position 152E of the surrounding region 152 on the second surface 152T. The first surface 151T and the second surface 152T which form the curved surface may be, for example, a spherical surface, a gradual paraboloidal surface, or a non-spherical surface such as a semi-ellipse surface. In this case, the back surface SB of the substrate S and the first surface 151T smoothly come into contact with each other, and damage to the back surface SB of the substrate S is prevented from being generated.

A corner located between an outer surface 152S of the lift pin 150 and the second surface 152T of the surrounding region 152 has the curved surface CV2. In other words, the corner located between the outer side surface 152S and the second surface 152T is subjected to chamfering processing.

According to the modified example 1, even in the case where the lift pin 150 is formed of an integrated member having electroconductivity, as a result of setting the surface roughness of the second surface 152T to be smaller than the surface roughness of the first surface 151T, damage to the back surface SB of the substrate S due to contact between the second surface 152T and the substrate S can be prevented from being generated. Moreover, as a result of forming the curved surface CV2, damage to the back surface SB of the substrate S can be prevented from being generated by the aforementioned action.

In addition, the lift pin 150 is electrically connected to the heater 20, and the lift pin 150 and the heater 20 have the same electrical potential. Because of this, even in cases where the lift pins 150 are accommodated in the opening holes 22, plasma to be generated above the substrate S does not become non-uniform, and it is possible to form a film having a uniform film-thickness profile on the substrate S by uniform plasma.

### Modified Example 2 of Lift Pin

FIG. 7 is a cross-sectional view showing a relevant part of a configuration of a modified example 2 of the lift pin according to the embodiment of the invention. In FIG. 7, identical reference numerals are used for the elements which are identical to those of the embodiment and the modified example 1, and explanations thereof are omitted or simplified here.

The modified example 2 is different from the above-mentioned embodiment in that a surrounding member is an electroconductive member.

Specifically, a lift pin 250 includes the above-described center member 51 and a surrounding member 252 formed of aluminum (electroconductive member). That is, in the modified example 2, the surrounding member 252 made of aluminum is employed instead of the surrounding member 52 formed of insulating ceramic.

Although an alumite coating (electrical insulator) on which aluminum is subjected to anodic oxidation treatment is formed on the second surface 252T of the surrounding member 252, the surface roughness of the first surface 51T is different from that of the second surface 252T, the surface roughness (second surface roughness) of the second surface 252T is smaller than the surface roughness of the first surface 51T.

Particularly, as the surface roughness of the first surface 51T, for example, a surface roughness Ra of 1 to 2 μm is adopted. Additionally, as the surface roughness of the second surface 252T, for example, a surface roughness Ra of 0.2 μm is adopted.

In the modified example 2, the upper surface of the center member 51 has a flat surface (flat); however, the invention is not limited to this structure. The first surface 51T and the second surface 252T may have a curved surface so that the center position 51C in the direction in which the lift pin 250 extends (the Z-direction) is located outside end position 252E of the surrounding member 252 on the second surface 252T. The first surface 51T and the second surface 252T which form the curved surface may be, for example, a spherical surface, a gradual paraboloidal surface, or a non-spherical surface such as a semi-ellipse surface. In this case, the back surface SB of the substrate S and the first surface 51T smoothly come into contact with each other, and damage to the back surface SB of the substrate S is prevented from being generated.

A corner located between an outer surface 252S of the surrounding member 252 and the second surface 252T of the surrounding member 252 has the curved surface CV2. In other words, the corner located between the outer side surface 252S and the second surface 252T is subjected to chamfering processing.

According to the modified example 2, even in the case where the surrounding member 252 and the center member 51 are formed of the same electroconductive member, as a result of setting the surface roughness of the second surface 252T to be smaller than the surface roughness of the first surface 51T, damage to the back surface SB of the substrate S due to contact between the second surface 252T and the substrate S can be prevented from being generated. Moreover, as a result of forming the curved surface CV2, damage to the back surface SB of the substrate S can be prevented from being generated by the aforementioned action.

Additionally, the center member 51 is electrically connected to the heater 20, the center member 51 and the heater 20 have the same electrical potential. Because of this, even in cases where the lift pins 250 are accommodated in the opening holes 22, plasma to be generated above the substrate S does not become non-uniform, and it is possible to form a film having a uniform film-thickness profile on the substrate S by uniform plasma.

### Modified Example 3 of Lift Pin

FIG. 8 is a cross-sectional view showing a relevant part of a configuration of a modified example 3 of the lift pin according to the embodiment of the invention. In FIG. 8, identical reference numerals are used for the elements which are identical to those of the embodiment and the modified examples 1 and 2, and explanations thereof are omitted or simplified here.

In the above-mentioned embodiment, as shown in FIGS. 3A, 3B, 6, and 7, the center member 51 and the surrounding member 52 adjacent to each other so that the end portion of the first surface 51T comes into contact with the end portion of the second surface 52T. The invention is not limited to the configurations shown in FIGS. 3A, 3B, 6, and 7. For example, as shown in FIG. 8, the second surface 52T may be connected to the first surface 51T via a step difference ST. In this case, a recess 55 is formed between the upper edge 52U of the surrounding member 52 and the first surface 51T (flat surface). The depth of the recess 55, that is, the distance between the upper edge 52U and the first surface 51T in the Z-direction is defined as Δt as shown in FIG. 8.

In other words, the direction in which the lift pin 350 extends (the Z-direction), the center position 51C of the center member 51 on the first surface 51T is lower than the position of the upper edge 52U of the surrounding member 52.

By moving up the substrate S using the lift pin 350 having this configuration as shown in FIG. 4, a cap between the first surface 51T of the center member 51 and the back surface SB of the substrate S is formed. For this reason, damage to the back surface SB of the substrate S due to contact of the end portion (edge) of the first surface 51T to the back surface SB of the substrate S is less likely to be generated.

### Modified Example 4 of Lift Pin

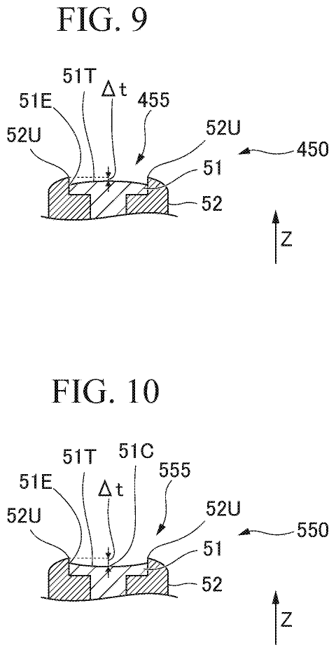

FIG. 9 is a cross-sectional view showing a relevant part of a configuration of a modified example 4 of the lift pin according to the embodiment of the invention. In FIG. 9, identical reference numerals are used for the elements which are identical to those of the embodiment and the modified examples 1 to 3, and explanations thereof are omitted or simplified here.

In the aforementioned modified example 3, the example is explained in which the recess 55 is formed between the upper edge 52U of the surrounding member 52 and the first surface 51T in the case where the first surface 51T is a flat surface. The modified example 4 is different from the modified example 3 in that a curved surface having a projected shape bulging in the Z-direction is formed on the first surface 51T.

The depth of the recess 455 at the end portion 51E of the first surface 51T (the same potion as that of the upper edge 52U as seen in the Z-direction), that is, the distance between the upper edge 52U and the end portion 51E in the Z-direction is defined as Δt as shown in FIG. 9.

In other words, the direction in which the lift pin 450 extends (the Z-direction), the end portion 51E of the center member 51 on the first surface 51T is lower than the position of the upper edge 52U of the surrounding member 52. Furthermore, the position of the center position 51C is lower than the position of the upper edge 52U of the surrounding member 52.

Similar to the above-mentioned modified example 3, in the case of moving up the substrate S using the lift pin 450 having the aforementioned configuration, a gap is formed between the first surface 51T of the center member 51 and the back surface SB of the substrate S. For this reason, damage to the back surface SB of the substrate S due to contact of the end portion 51E (edge) of the first surface 51T to the back surface SB of the substrate S is less likely to be generated.

Note that, in the modified example 4, the shape of the projected curved surface formed on the first surface 51T may be, for example, a spherical surface, a gradual paraboloidal surface, or a non-spherical surface such as a semi-ellipse surface.

### Modified Example 5 of Lift Pin

FIG. 10 is a cross-sectional view showing a relevant part of a configuration of a modified example 5 of the lift pin according to the embodiment of the invention. In FIG. 10, identical reference numerals are used for the elements which are identical to those of the embodiment and the modified examples 1 to 4, and explanations thereof are omitted or simplified here.

In the aforementioned modified example 4, the example is explained in which the recess 455 is formed between the upper edge 52U of the surrounding member 52 and the first surface 51T in the case where the curved surface having a projected shape bulging in the Z-direction is formed on the first surface 51T. The modified example 5 is different from the modified example 4 in that a curved surface having a recessed shape is formed on the first surface 51T.

The depth of the recess 555 at the center position 51C of the first surface 51T, that is, the distance between the upper edge 52U and the center position 51C in the Z-direction is defined as Δt as shown in FIG. 10.

In other words, the direction in which the lift pin 550 extends (the Z-direction), the position of the center position 51C of the center member 51 on the first surface 51T is lower than the position of the upper edge 52U of the surrounding member 52. Moreover, the position of the end portion 51E is lower than the position of the upper edge 52U of the surrounding member 52.

Similar to the above-mentioned modified examples 3 and 4, in the case of moving up the substrate S using the lift pin 550 having the aforementioned configuration, a gap is formed between the first surface 51T of the center member 51 and the back surface SB of the substrate S. For this reason, damage to the back surface SB of the substrate S due to contact of the end portion 51E (edge) of the first surface 51T to the back surface SB of the substrate S is less likely to be generated.

Note that, in the modified example 5, the shape of the recessed curved surface formed on the first surface 51T may be, for example, a spherical surface, a gradual paraboloidal surface, or a non-spherical surface such as a semi-ellipse surface.

### EXAMPLES

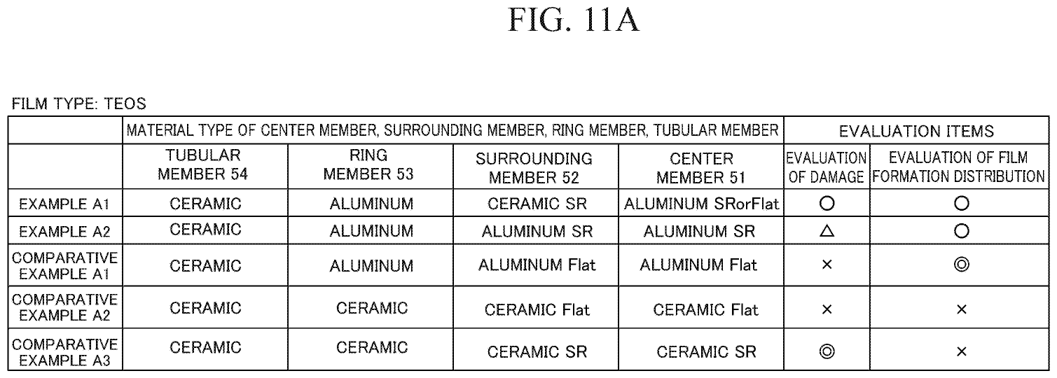

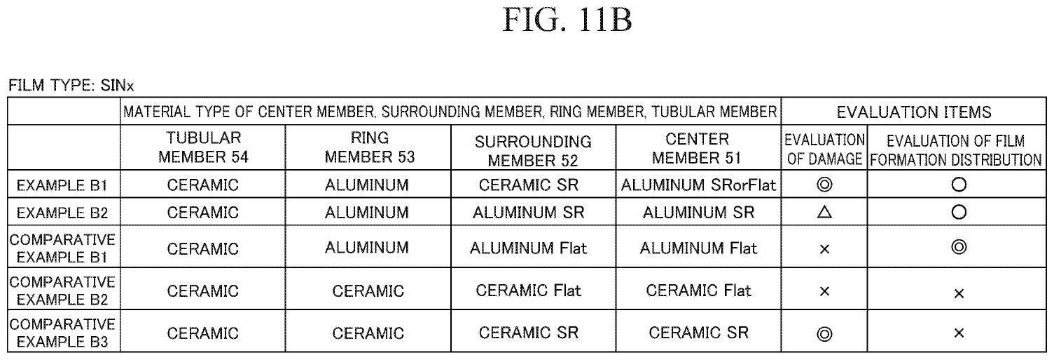

Next, Examples of the invention will be described with reference to FIGS. 11A and 11B.

FIGS. 11A and 11B show results in which material types of the center member 51, the surrounding member 52, the ring member 53, and the tubular member 54 according to the above-mentioned embodiment were varied, two kinds of films were each formed on a substrate, and an evaluation of a film formation distribution and an evaluation of occurrence of damage to a back surface of a substrate were carried out.

As films to be formed, a TEOS film (tetraethyl orthosilicate film) shown in FIG. 11A and a SiNx film (silicon nitride film) shown in FIG. 11B were employed.

### (Evaluation Item: Evaluation of Damage)

In “Evaluation of Damage”, difficulty of applying damage to a back surface of a glass substrate due to a lift pin was evaluated.

Specifically, reference sign “⊚” means “damage to the substrate was not generated (Excellence)”, reference sign “◯” means “damage to the substrate was slightly generated (Good)”, reference sign “Δ” means “although damage to the substrate was generated, it was in an allowable range (Pass)”, and reference sign “x” means “damage to the substrate was generated and it was out of an allowable range (Failure)”.

### (Evaluation Item: Evaluation of Film Formation Distribution)

In “Evaluation of Film Formation Distribution”, whether or not uniformity of a film-thickness profile formed on a top surface of the glass substrate was excellent.

Specifically, reference sign “⊚” means that a film-thickness profile was excellent (uniform), reference sign “◯” means that a film-thickness profile was good, reference sign “Δ” means that a film-thickness profile is pass, and reference sign “x” means that a film-thickness profile was failure (non-uniform).

### (Material Types)

Regarding materials used to form the center member 51, the surrounding member 52, the ring member 53, and the tubular member 54, “CERAMIC” means that ceramic was selected as a constituent material forming the member, and “ALUMINUM” means that aluminum was selected as a constituent material forming the member.

Furthermore, “ALUMINUM SR” means that aluminum was selected as a constituent material forming the member and a curved surface was formed on the top surfaces of the center member 51 and the surrounding member 52 (the first surface 51T and the second surface 52T).

Additionally, “ALUMINUM Flat” means that aluminum was selected as a constituent material forming the member and a flat surface was formed on the top surfaces of the center member 51 and the surrounding member 52 (the first surface 51T and the second surface 52T).

Moreover, “ALUMINUM SR or Flat” means that, in the case where aluminum was selected as a constituent material forming the member, the top surface (the first surface 51T) of the center member 51 was a curved surface or a flat surface. That is, each of Examples A1 and B1 which will be described below shows the results in the case where the top surface of the center member 51 was a curved surface and in the case where the top surface of the center member 51 was a flat surface.

Furthermore, in all of “ALUMINUM”, “ALUMINUM SR”, and “ALUMINUM Flat”, an alumite coating is formed on the top surface by anodic oxidation.

In addition, “CERAMIC SR” means that ceramic was selected as a constituent material forming the member and a curved surface was formed on the top surfaces of the center member 51 and the surrounding member 52 (the first surface 51T and the second surface 52T).

Moreover, “CERAMIC Flat” means that ceramic was selected as a constituent material forming the member and the top surfaces of the center member 51 and the surrounding member 52 (the first surface 51T and the second surface 52T) were each a flat surface.

### (TEOS Film)

The following points were apparent.

### Comparative Examples A1, A2, and A3

The result of at least one of the evaluation of damage and the evaluation of film formation distribution was “x (Failure)”. Particularly, in the case where ceramic (CERAMIC SR, CERAMIC Flat) is used as a material of the center member 51, it was apparent that the result of the evaluation of film formation distribution is poor.

It is thought that, the reason is that plasma becomes non-uniform at the positions corresponding to the lift pins due to employing ceramic as a material of the center member 51 and it adversely affects a film formation distribution.

It was apparent that, although the result of the evaluation of damage was excellent by using CERAMIC SR as a material of the surrounding member 52, the results of the evaluation of damage were poor in the case where CERAMIC Flat or ALUMINUM Flat was used.

It is thought that, the reason is that damage was easily generated due to making the top surface of the surrounding member 52 flat.

### Examples A1 and A2

In the case of Example A1, both results of the evaluation of damage and the evaluation of film formation distribution were “◯ (Good)”. Additionally, in the case of Example A2, the result of the evaluation of damage was “Δ (Pass)” and the result of the evaluation of film formation distribution was “◯ (Good)”.

For this reason, it was apparent that, as a combination of the center member 51 and the surrounding member 52, by employing ALUMINUM SR or Flat as a material of the center member 51 and by employing CERAMIC SR as a material of the surrounding member 52, excellent results can be obtained in both evaluations, that is, the evaluation of damage and the evaluation of film formation distribution.

Furthermore, it was apparent that, even in the case where ALUMINUM is adopted without using CERAMIC as a material of the surrounding member 52, by employing ALUMINUM SR as a material of the center member 51 and the surrounding member 52, damage generated on the back surface of the substrate was in an allowable range.

### (SiNx Film)

The following points were apparent.

### Comparative Examples B1, B2, and B3

The result of at least one of the evaluation of damage and the evaluation of film formation distribution was “x (Failure)”. Particularly, in the case where ceramic (CERAMIC SR, CERAMIC Flat) is used as a material of the center member 51, it was apparent that the result of the evaluation of film formation distribution is poor.

It is thought that, the reason is that plasma becomes non-uniform at the positions corresponding to the lift pins due to employing ceramic as a material of the center member 51 and it adversely affects a film formation distribution.

It was apparent that, although the result of the evaluation of damage was excellent by using CERAMIC SR as a material of the surrounding member 52, the results of the evaluation of damage were poor in the case where CERAMIC Flat or ALUMINUM Flat was used.

It is thought that, the reason is that damage was easily generated due to making the top surface of the surrounding member 52 flat.

### Examples B1 and B2

In the case of Example B1, the result of the evaluation of damage was “⊚ (Excellence)” and the result of the evaluation of film formation distribution was “◯ (Good)”. Additionally, in the case of, Example B2, the result of the evaluation of damage was “Δ (Pass)” and the result of the evaluation of film formation distribution was “◯ (Good)”.

For this reason, it was apparent that, as a combination of the center member 51 and the surrounding member 52, by employing ALUMINUM as a material of the center member 51 and by employing CERAMIC as a material of the surrounding member 52, excellent results can be obtained in both evaluations, that is, the evaluation of damage and the evaluation of film formation distribution.

Furthermore, it was apparent that, even in the case where ALUMINUM is adopted without using CERAMIC as a material of the surrounding member 52, by employing ALUMINUM SR as a material of the center member 51 and the surrounding member 52, damage generated on the back surface of the substrate was in an allowable range.

As described above, while preferred embodiments of the invention have been described and shown above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

In the above-mentioned embodiment and the modified examples, although the case was described where the vacuum processing apparatus 100 is applied to a plasma CVD apparatus known as a film formation apparatus, the invention is not limited to the plasma CVD apparatus. The vacuum processing apparatus according to the embodiment of the invention is also applicable to an etching apparatus, an ashing apparatus, or the like.

### INDUSTRIAL APPLICABILITY

The invention is widely applicable to: a lift pin that prevents damage to a back surface of a substrate from being generated and can improve uniformity of plasma generated above a top surface of a substrate; and a vacuum processing apparatus provided with the lift pin.

### DESCRIPTION OF REFERENCE NUMERALS

10 vacuum chamber, 11 lower chamber, 12 upper chamber, 13 electrode flange, 20 heater (substrate holder), 21 substrate mounting surface, 22 opening hole, 22L lower opening, 22U upper opening, 23 heater base, 30 high-frequency power supply, 40 lifting mechanism, 45 lift pin base, 50, 150, 250, 350, 450, 550 lift pin, 51 center member, 51C, 151C center position, 51H head, 51M, 52M main body, 51R rod, 51T, 151T first surface, 52, 252 surrounding member, 52E, 152E, 252E end position, 52S, 152S, 252S outer side surface, 52T, 152T, 252T second surface, 52U upper edge, 53 ring member, 54 tubular member, 55, 455, 555 recess, 60 vacuum pump, 70 gas supplier, 75 shower plate, 80 door valve, 100 vacuum processing apparatus, 151 center region, 152 surrounding region (surrounding member), CV2 curved surface, S substrate, SB back surface, SL long side, SS short side, ST step difference.

What is claimed is:

1. A lift pin to be in contact with a substrate having a process-target surface and a non-processed surface, the lift pin comprising:
a center member that includes: a first surface having a first surface roughness and including an electrical insulator; and a main body that is an electroconductive member, the center member facing the non-processed surface of the substrate;
a surrounding member that includes a second surface having a second surface roughness smaller than the first surface roughness and including an electrical insulator, the surrounding member surrounding a periphery of the center member, the surrounding member facing the non-processed surface of the substrate.

2. The lift pin according to claim 1, wherein
the surrounding member is an electrical insulating member.

3. The lift pin according to claim 1, wherein
the surrounding member is an electroconductive member.

4. The lift pin according to claim 3, wherein
the center member and the surrounding member form an integrated body formed of an electroconductive member.

5. The lift pin according to claim 1, wherein
the first surface and the second surface have a curved surface so that a center position of the center member on the first surface in a direction in which the lift pin extends is located outside an end position of the surrounding member on the second surface.

6. The lift pin according to claim 1, wherein
a corner located between an outer surface of the surrounding member and the second surface of the surrounding member has a curved surface.

7. The lift pin according to claim 1, wherein
the first surface and the second surface is contactable to the non-processed surface of the substrate.

8. A vacuum processing apparatus, comprising:
a vacuum chamber;
a substrate holder having a substrate mounting surface on which the substrate is to be mounted, an opening hole that opens at the substrate mounting surface, the substrate holder being disposed inside the vacuum chamber;
the lift pin according to claim 1 which is provided at a position corresponding to the opening hole and is capable of moving up and down in a vertical direction inside the opening hole;
a high-frequency power supply that generates plasma in the vacuum chamber; and
a lifting mechanism that moves the lift pin relative to the substrate holder in a vertical direction.
